(19) United States
(12) Patent Application Publication
(10) Pub. No.: US 2024/0334647 A1
(43) Pub. Date: Oct. 3, 2024

(54) LIQUID-COOLING HEAT EXCHANGE DEVICE

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/603,308

(22) Filed: Mar. 13, 2024

(30) Foreign Application Priority Data
Mar. 27, 2023 (CN) 202310307670.7

(51) Int. Cl. H05K 7/20; B01D 35/30

(52) U.S. Cl. CPC H05K 7/20272; B01D 35/30; H05K 7/20772; H05K 7/20836

(57) ABSTRACT

The present disclosure discloses a liquid-cooling heat exchange device at least including a box body internally provided with a temperature control component, a first pipeline, and a second pipeline. The temperature control component has a first runner and a second runner respectively interconnected to the first pipeline and the second pipeline to form a first loop and a second loop, where the first loop and the second loop exchange heat through contact. The first pipeline is provided with a filter component to ensure that a liquid flowing along the first loop flows through the filter component, where the filter component at least includes a shell and a filter element, the shell is detachably connected to the first pipeline, and the filter element is fixedly arranged inside the shell.

### CROSS REFERENCE TO RELATED APPLICATION

This application claims priority to Chinese Patent Application No. 202310307670.7, titled “LIQUID-COOLING HEAT EXCHANGE DEVICE” and filed to the China National Intellectual Property Administration on Mar. 27, 2023, the entire contents of which are incorporated herein by reference.

### TECHNICAL FIELD

The present disclosure relates to the field of heat dissipation technology for electronic devices, and more particularly, to a liquid-cooling heat exchange device.

### BACKGROUND

With the rapid development of national informatization and digitization, data center rooms have become a significant constituent part of national economic development. With the expansion of data centers and large-scale use of high power density servers, heat production of a single cabinet has sharply increased. In one aspect, heat produced by the high power density servers needs to be taken away timely, otherwise damage may be caused to devices, resulting in economic losses. In another aspect, power of refrigeration devices required for high heat dissipation has increased manyfold, which increases energy consumption of the data centers.

The existing data center rooms mainly adopt mature air-cooling technologies such as industrial air conditioning. However, higher energy consumption of air conditioning equipment generally leads to higher PUE values of the data center rooms. To solve the heat dissipation problem of high power consumption IT equipment, the data centers have begun to adopt liquid-cooling technologies. Cooling efficiency of the liquid-cooling technologies is significantly higher than that of the air-cooling technologies, such that the heat dissipation problem of high power consumption IT equipment can be effectively solved, and energy consumption of cooling systems can be reduced.

However, in the data center rooms that currently adopt the liquid-cooling technologies, commonly-used liquid-cooling heat exchange devices cannot guarantee that liquids entering liquid-cooled apparatuses do not contain impurities adversely affecting operation of the devices.

### SUMMARY

Objectives of the present disclosure are to provide a liquid-cooling heat exchange device. A filter component is additionally provided to filter a coolant liquid in a liquid-cooling server container to ensure that the coolant liquid remains in a pollution-free state after heat exchange, thereby avoiding adversely affecting operation of the device due to impurities brought in by the coolant liquid reentering the liquid-cooling server container.

To achieve the above objectives, the present disclosure provides a liquid-cooling heat exchange device, which at least includes a box body, where the box body is internally provided with a temperature control component, a first pipeline, and a second pipeline. The temperature control component has a first runner and a second runner, and the first runner and the second runner are respectively interconnected to the first pipeline and the second pipeline to form a first loop and a second loop, wherein the first loop and the second loop exchange heat through contact. The first pipeline is provided with a filter component to ensure that a liquid flowing along the first loop flows through the filter component, where the filter component at least includes a shell and a filter element, the shell is detachably connected to the first pipeline, and the filter element is fixedly arranged in the shell.

As a further improvement of the above technical solutions, the first pipeline includes a container inlet pipe and a container return pipe, where the container inlet pipe and the container return pipe are respectively connected to two ends of the first runner. The container inlet pipe and the container return pipe are connected to a container at one end away from the first runner, such that a liquid inside the container flows through the first loop and exchanges heat with the second loop.

As a further improvement of the above technical solutions, a pump body is arranged on the container inlet pipe, and the liquid inside the container circulates along the first loop by means of the pump body.

As a further improvement of the above technical solutions, both the container inlet pipe and the container return pipe are provided with a filter component, such that the liquid flowing to the first runner and the liquid flowing to the container can flow through the filter component.

As a further improvement of the above technical solutions, the container return pipe is a right-angle structure, such that the container return pipe is disposed on a left or right side of the box body.

As a further improvement of the above technical solutions, a conductivity meter is arranged on the container return pipe to detect electrical conductivity of the liquid flowing into the container.

As a further improvement of the above technical solutions, a temperature sensor is provided on the container return pipe to obtain a temperature of the liquid flowing out of the first runner.

As a further improvement of the above technical solutions, the second pipeline includes an external circulation inlet pipe and an external circulation return pipe, where the external circulation inlet pipe and the external circulation return pipe are respectively connected to two ends of the second runner. The external circulation inlet pipe and the external circulation return pipe penetrate through the box body and connect an external circulation system at one end away from the second runner, such that a liquid flowing out of the external circulation system flows into the second loop and exchanges heat with the first loop.

As a further improvement of the above technical solutions, a regulating valve is arranged on the external circulation inlet pipe to regulate a flow rate of the liquid flowing into the second runner through the external circulation system.

As a further improvement of the above technical solutions, the external circulation inlet pipe is further provided with a pressure sensor to detect a pressure of the liquid flowing into the second runner through the external circulation system.

As can be seen from the technical solutions provided in one or more embodiments of the present disclosure, the temperature control component is provided to exchange heat with the liquid inside the liquid-cooling server container, to ensure that the coolant liquid can stay within a predetermined temperature interval for a long time, thereby cooling the device.

Furthermore, the filter component is additionally provided to filter the coolant liquid in the liquid-cooling server container to ensure that the coolant liquid remains in a pollution-free state after heat exchange, thereby avoiding adversely affecting operation of the device due to impurities brought in by the coolant liquid reentering the liquid-cooling server container.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a liquid-cooling heat exchange device according to an embodiment of the present disclosure;

FIG. 2 is a schematic structural diagram of a liquid-cooling heat exchange device according to an embodiment of the present disclosure;

FIG. 3 is a schematic structural diagram of a filter component according to an embodiment of the present disclosure;

FIG. 4 is a schematic structural diagram of a shell according to an embodiment of the present disclosure; and

FIG. 5 is a schematic structural diagram of a shell according to an embodiment of the present disclosure.

Reference numerals in the accompanying drawings:
box body 10; temperature control component 20; filter component 30; shell 301; filter element 302; first pipeline 40; container inlet pipe 401; pump body 4011; container return pipe 402; second pipeline 50; external circulation inlet pipe 501; external circulation return pipe 502; conductivity meter 60; and controller 70.

### DETAILED DESCRIPTION

Detailed description of the embodiments of the present disclosure will further be made below with reference to the accompanying drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

The present disclosure provides a liquid-cooling heat exchange device, which is described in detail below. It is to be noted that the description order of the following embodiments does not limit the preferred order of the embodiments in the present disclosure. In the following embodiments, description of various embodiments may be focused on differentially, and reference may be made to related descriptions of other embodiments for a part not expatiated in a certain embodiment.

With the growth of computing power of data centers, heat flux density of the data centers continues to increase. Traditional air-cooling systems used in the data centers gradually become unable to withstand high heat generated by high computing power servers. By contrast, liquid-cooling systems have gradually become a necessary choice for new-generation data centers due to their higher heat dissipation efficiency.

To ensure continuous cooling effects of coolant liquids inside liquid-cooling server containers, most of existing data center rooms use liquid-cooling heat exchange devices to connect the liquid-cooling server containers for heat exchange, to control temperature of the coolant liquids inside the liquid-cooling server containers within a reasonable range and to ensure normal operation of the liquid-cooling servers.

The existing liquid-cooling heat exchange devices can only ensure that the temperature of the coolant liquids in the liquid-cooling server containers changes when exchanging heat. However, it is uncertain that the coolant liquids reentering the liquid-cooling server containers remain in a pollution-free state after heat exchange, which may easily cause impurities to enter the liquid-cooling server containers, and thus having negative effects on servers.

Furthermore, arranging a filter apparatus directly on a heat exchange component is not convenient for replacing the filter apparatus after long-term use of the heat exchange component.

In view of this, the embodiments of the present disclosure provide a liquid-cooling heat exchange device. A filter component is arranged to filter a cooling liquid during the process of heat exchange, to ensure that the cooling liquid reentering the liquid-cooling server container after the heat exchange is in a pollution-free state. Furthermore, the filter component adopts a detachable structure, making it easy for replacement and installation by operation and maintenance personnel. A detailed description is made below.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

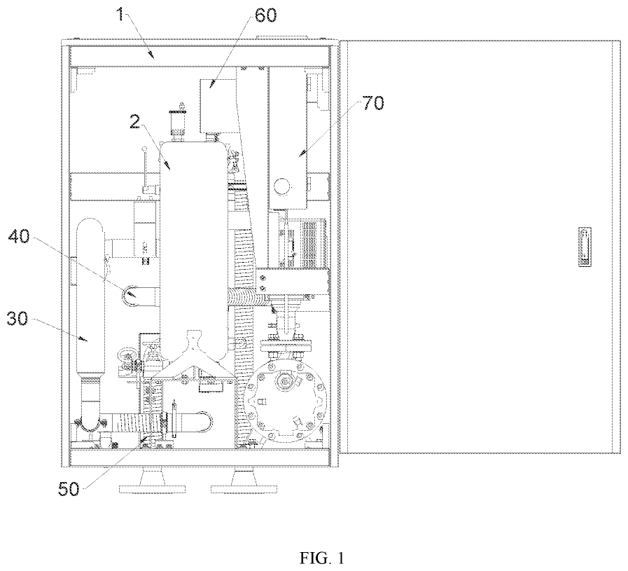

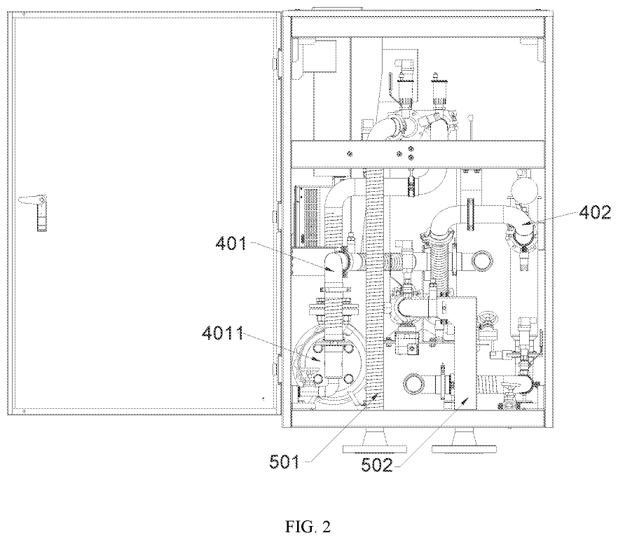

Referring to FIG. 1 and FIG. 2, a liquid-cooling heat exchange device at least includes a box body 10, which is internally provided with a temperature control component 20, a first pipeline 40, and a second pipeline 50. The temperature control component 20 has a first runner and a second runner, and the first runner and the second runner are respectively interconnected to the first pipeline 40 and the second pipeline 50 to form a first loop and a second loop. The first loop and the second loop exchange heat through contact. In this way, the coolant liquid inside the liquid-cooling server container and external water may flow through the first loop and the second loop respectively to complete the heat exchange between the two liquids, thereby achieving an objective of regulating temperature of the coolant liquid. The first pipeline 40 is provided with a filter component 30 to ensure that a liquid flowing along the first loop flows through the filter component 30, where the filter component 30 at least includes a shell 301 and a filter element 302, the shell 301 is detachably connected to the first pipeline 40, and the filter element 302 is fixedly arranged in the shell 301. Through the above mentioned way, the coolant liquid flowing out of the liquid-cooling server container can be maintained in a pollution-free state when the coolant liquid flows back into the liquid-cooling server container because no impurities are added during the process of heat exchange.

Further, the first pipeline 40 includes a container inlet pipe 401 and a container return pipe 402. The container inlet pipe 401 and the container return pipe 402 are respectively connected to two ends of the first runner. The container inlet pipe 401 and the container return pipe 402 are connected to a container at one end away from the first runner, such that a liquid inside the container flows through the first loop and exchanges heat with the second loop. Still further, a pump body 4011 is arranged on the container inlet pipe 401, and the liquid inside the container circulates along the first loop by means of the pump body 4011, thereby changing the temperature of the liquid inside the liquid-cooling server container.

Still further, the second pipeline 50 includes an external circulation inlet pipe 501 and an external circulation return pipe 502. The external circulation inlet pipe 501 and the external circulation return pipe 502 are respectively connected to two ends of the second runner. The external circulation inlet pipe 501 and the external circulation return pipe 502 penetrate through the box body 10 and connect an external circulation system at one end away from the second runner, such that a liquid flowing out of the external circulation system flows into the second loop and exchanges heat with the first loop.

All the container inlet pipe 401, the container return pipe 402, the external circulation inlet pipe 501, and the external circulation return pipe 502 may be comprised of hard pipelines and soft pipelines, respectively. The soft pipelines can compensate for size and assembly errors, facilitating layout and installation of the entire pipelines. The hard pipelines may be employed to connect components such as sensors and valve bodies.

Moreover, a plurality of on/off valves are connected in series with the container inlet pipe 401, the container return pipe 402, the external circulation inlet pipe 501, and the external circulation return pipe 502, respectively. The plurality of on/off valves are successively arranged at intervals along the corresponding pipelines, such that in subsequent maintenance, it is not necessary to discharge all the liquids for maintenance. Instead it is only required to turn off the on/off valves at two ends of a corresponding maintenance point, making the maintenance more convenient.

After long-term operation of the coolant liquid inside the first loop, shortage of the coolant liquid may be caused by volatilization of the coolant liquid. To facilitate replenishment of the coolant liquid, a container branch is arranged in the container inlet pipe 401 and/or the container return pipe 402, and the container branch is connected to a liquid charging/discharging port.

Specifically, the liquid charging/discharging port includes a liquid charging/discharging cut-off valve and a quick connector. One end of the liquid charging/discharging cut-off valve is interconnected to the container branch, and other end of the liquid charging/discharging cut-off valve is interconnected to the quick connector. In this way, when liquid replenishment is needed, an external liquid replenishment device connector may be connected to the quick connector, and then the liquid charging/discharging cut-off valve may be opened for liquid replenishment. After the liquid replenishment is completed, the liquid charging/discharging cut-off valve may be closed first, and then the external liquid replenishment device connector is removed from the quick connector.

In practical applications, a plate heat exchanger is employed for heat exchange of the liquid in the above solutions. Specifically, the liquid inside the liquid-cooling server container enters the first runner of the plate heat exchanger through the container inlet pipe 401, and the liquid in the external circulation system enters the second runner of the plate heat exchanger through the external circulation inlet pipe 501. Heat is transferred based on a temperature differential between the two liquids. After the heat exchange, the two liquids enter the container return pipe 402 and the external circulation return pipe 502, respectively.

For example, after a server runs for a certain period of time, its temperature rises. To keep the temperature of the server within a preset range, the liquid inside the liquid-cooling server container is introduced into the first runner by means of the pump body 4011. At this moment, the temperature of the liquid inside the first runner is higher than the temperature of the liquid inside the second runner. After the heat exchange, the temperature of the liquid entering the container return pipe 402 drops. In this way, it is ensured that the temperature of the liquid flowing back into the liquid-cooling server container is lower than the temperature of the liquid flowing out of the liquid-cooling server container.

In an implementable embodiment, both the container inlet pipe 401 and the container return pipe 402 are provided with a filter component 30, such that both the liquid flowing to the first runner and the liquid flowing to the container can flow through the filter component 30. In this way, it can be ensured that no foreign objects flow into the first channel or the liquid-cooling server container, preventing from causing blockage of the pipeline or the container due to accumulation of the foreign object, thereby avoiding adversely affecting flow of the liquid or operation of the device. Both the container inlet pipe 401 and the container return pipe 402 are comprised of two pipelines, and an internal thread structure is respectively provided on an inner wall of an opposite end of the two pipelines. Two ends of the shell 301 of the filter component 30 extend outward, and an external thread structure intermeshing the internal thread structure is provided along an outer wall. The filter component 30 is detachably connected to the container inlet pipe 401 and the container return pipe 402 through the intermesh between the internal thread structure and the external thread structure.

Unlike the aforementioned manner of arranging the filter component 30 between the two pipelines, in an implementable embodiment, the filter component 30 is arranged at an end of the pipeline, which means that only one end of the filter component 30 has the external threaded structure. This method facilitates disassembly and assembly of the filter component 30 by the operation and maintenance personnel. To improve filtration intensity, the filter component 30 may also be concurrently arranged between the two pipelines and at the ends thereof. When a flow velocity of the liquid is fast and the flow rate of the liquid is high, the filter component 30 positioned at the end of the pipeline is subjected to greater fluid impact force. Thus, the filter component 30 arranged between the two pipelines may be used for long time.

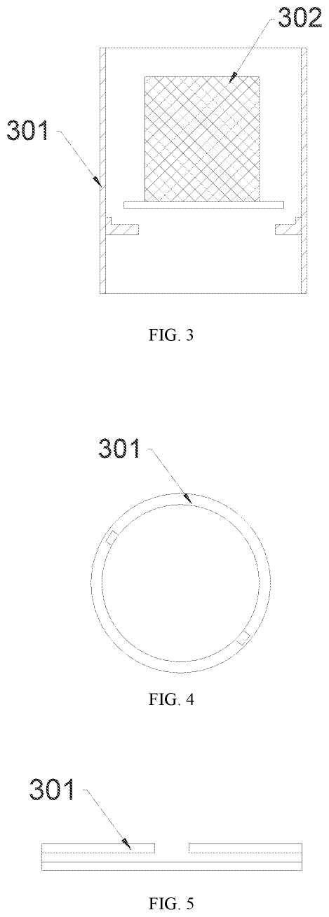

Further, as shown in FIG. 3, FIG. 4, and FIG. 5, the shell 301 of the filter component 30 is internally provided with a fixture slot along an inner wall, and the filter element 302 is provided with a fixture block. The filter element 302 and the shell 301 can be fixedly connected through intermesh between the fixture slot and the fixture block, such that the filter element 302 is fixedly arranged inside the shell 301, facilitating the replacement of the filter element 302.

In an implementable embodiment, a conductivity meter 60 is arranged on the container return pipe 402 to detect electrical conductivity of the liquid flowing into the container. When the conductivity meter 60 displays that the electrical conductivity of the liquid is too high at this moment, this means that there are more impurities in the current liquid, and an alarm may be triggered. In this case, the operation and maintenance personnel may replace the liquid inside the liquid-cooling server container and the filter component 30 according to the above situations to prevent occurrence of blocking the pipelines by the impurities.

In an implementable embodiment, the container return pipe 402 adopts a right-angle structure, such that the container return pipe 402 may be disposed on a left or right side of the box body 10 according to internal structural layout requirements of the liquid-cooling heat exchange device. In this way, through reasonable structural design, compared to similar devices, daily maintenance and repair can be completed better and faster. Correspondingly, the container inlet pipe 401 may also adopt a right-angle structure to achieve interaction with the container return pipe 402.

In an implementable embodiment, a temperature sensor is provided on the container return pipe 402 to obtain the temperature of the liquid flowing out of the first runner. The liquid-cooling heat exchange device has a controller 70, and a communication line (wired or wireless communication line) is provided between the temperature sensor and the controller 70. The controller 70 can receive a signal sent by the temperature sensor, thereby obtaining the real-time temperature of the liquid inside the container return pipe 402. When the temperature of the liquid inside the container return pipe 402 exceeds the preset range, the temperature detected by the temperature sensor may be fed back to the controller 70 through the above communication line, and then the controller 70 sends a reminder in the form of sound and light. The pump body 4011 can adjust the flow rate of the liquid accordingly based on the above detection data.

For example, assuming an optimal temperature interval for the liquid (i.e. the coolant liquid) after heat exchange is set to P1, if the temperature sensor detects that a temperature value of the container return pipe 402 after the first loop starts cycling is P2, the value P2 is sent to the controller 70. After the value P2 is obtained, the controller 70 compares it with a set optimal hydraulic range P1. When P2>P1, the temperature of the coolant liquid inside the container return pipe 402 is too high to achieve the effects of cooling the server. In this case, the controller 70 adjusts the temperature of the liquid supplied by the external circulation system, thereby changing the temperature of the liquid inside the second runner, such that the coolant liquid inside the first runner exchanges heat with the liquid whose temperature is changed. Furthermore, the controller 70 can also adjust an opening degree of the pump body 4011 to increase or decrease the flow rate of the liquid flowing through the first runner based on the current value P2.

In an implementable embodiment, a regulating valve is provided on the external circulation inlet pipe 501 to regulate a flow rate of the liquid flowing into the second runner through the external circulation system. In this way, the flow rate required for the heat exchange may be adjusted in conjunction. When the current cooling demand is higher, the flow rate of the liquid may be increased; otherwise, the flow rate of the liquid may be reduced.

Further, a pressure sensor is also arranged on the external circulation inlet pipe 501 to detect a pressure of the liquid flowing into the second runner through the external circulation system, thereby determining whether the current flow rate through the external circulation inlet pipe 501 is consistent with an opening degree of the regulating valve.

Still further, the pressure sensor is installed on a ball valve. When a pressure of the liquid is within a preset range, the ball valve is in a normally open state. When the pressure sensor requires maintenance or in other situations, the operation and maintenance personnel may manually close the ball valve.

In an implementable embodiment, a flow meter is arranged on the container inlet pipe 401 to monitor the flow rate of the coolant liquid flowing out of the liquid-cooling server container. The flow meter is electrically connected to a controller 70, which can receive a signal sent by the flow meter, obtain real-time flow rate data of the liquid inside the flow meter, and determine operation of the liquid-cooling heat exchange device based on the flow rate data.

As can be seen from the technical solutions provided in one or more embodiments of the present disclosure, the temperature control component 20 is provided to exchange heat with the liquid inside the liquid-cooling server container, to ensure that the coolant liquid can stay within the predetermined temperature interval for a long time, thereby cooling the device.

Furthermore, the filter component 30 is additionally provided to filter the coolant liquid in the liquid-cooling server container to ensure that the coolant liquid remains in a pollution-free state after heat exchange, thereby avoiding adversely affecting operation of the device due to impurities brought in by the coolant liquid reentering the liquid-cooling server container.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A liquid-cooling heat exchange device at least comprising a box body, wherein the box body is internally provided with a temperature control component, a first pipeline, and a second pipeline;
the temperature control component has a first runner and a second runner, and the first runner and the second runner are respectively interconnected to the first pipeline and the second pipeline to form a first loop and a second loop, wherein the first loop and the second loop exchange heat through contact; and
the first pipeline is provided with a filter component to ensure that a liquid flowing along the first loop flows through the filter component, wherein the filter component at least comprises a shell and a filter element, the shell is detachably connected to the first pipeline, and the filter element is fixedly arranged in the shell.

2. The liquid-cooling heat exchange device according to claim 1, wherein the first pipeline comprises a container inlet pipe and a container return pipe, and the container inlet pipe and the container return pipe are respectively connected to two ends of the first runner; and
the container inlet pipe and the container return pipe are connected to a container at one end away from the first runner, such that a liquid inside the container flows through the first loop and exchanges heat with the second loop.

3. The liquid-cooling heat exchange device according to claim 2, wherein a pump body is arranged on the container inlet pipe, and the liquid inside the container circulates along the first loop by means of the pump body.

4. The liquid-cooling heat exchange device according to claim 3, wherein both the container inlet pipe and the container return pipe are provided with the filter component, such that the liquid flowing to the first runner and the liquid flowing to the container flow through the filter component.

5. The liquid-cooling heat exchange device according to claim 4, wherein the container return pipe is a right-angle structure, such that the container return pipe is disposed on a left or right side of the box body.

6. The liquid-cooling heat exchange device according to claim 5, wherein a conductivity meter is arranged on the container return pipe to detect electrical conductivity of the liquid flowing into the container.

7. The liquid-cooling heat exchange device according to claim 1, wherein a temperature sensor is provided on the container return pipe to obtain a temperature of the liquid flowing out of the first runner.

8. The liquid-cooling heat exchange device according to claim 7, wherein the second pipeline comprises an external circulation inlet pipe and an external circulation return pipe, and the external circulation inlet pipe and the external circulation return pipe are respectively connected to two ends of the second runner; and
the external circulation inlet pipe and the external circulation return pipe penetrate through the box body and connect an external circulation system at one end away from the second runner, such that a liquid flowing out of the external circulation system flows into the second loop and exchanges heat with the first loop.

9. The liquid-cooling heat exchange device according to claim 8, wherein a regulating valve is arranged on the external circulation inlet pipe to regulate a flow rate of the liquid flowing into the second runner through the external circulation system.

10. The liquid-cooling heat exchange device according to claim 9, wherein the external circulation inlet pipe is further provided with a pressure sensor to detect a pressure of the liquid flowing into the second runner through the external circulation system.
